(19) United States
(12) Patent Application Publication
(10) Pub. No.: US 2023/0420438 A1
(43) Pub. Date: Dec. 28, 2023

(54) SEMICONDUCTOR PACKAGING

(71) Applicant: Taiwan Semiconductor Manufacturing Co., Ltd., Hsinchu (TW)

(72) Inventors: Tien-Chung YANG, Hsinchu (TW); Li-Hsien HUANG, Hsinchu (TW); Ming-Feng WU, Hsinchu (TW); Yao-Chun CHUANG, Hsinchu (TW); Jun HE, Hsinchu (TW)

(73) Assignee: Taiwan Semiconductor Manufacturing Co., Ltd., Hsinchu (TW)

(21) Appl. No.: 17/849,300

(22) Filed: Jun. 24, 2022

(51) Int. Cl. H01L 25/18; H01L 23/00; H01L 23/498; H01L 23/31

(52) U.S. Cl. CPC H01L 25/18; H01L 2224/29099; H01L 24/05; H01L 23/49827; H01L 23/3128; H01L 24/73; H01L 24/27; H01L 24/32; H01L 24/29; H01L 2224/16145; H01L 2224/0401; H01L 2224/05582; H01L 2224/73204; H01L 2224/16227; H01L 2224/2761; H01L 2224/32225; H01L 24/16

(57) ABSTRACT

The present disclosure describes a structure that joins semiconductor packages and a method for forming the structure. The structure includes an adhesion layer in contact with a first semiconductor package and a first joint pad in contact with the adhesion layer. The structure further includes a film layer disposed on the first semiconductor package and the first joint pad, where the film layer includes a slanted sidewall, the slanted sidewall covers an end portion of the adhesion layer and a first portion of the first joint pad, and the slanted sidewall exposes a second portion of the first joint pad. The structure further includes a solder ball attached to the second portion of the first joint pad and a second joint pad of a second semiconductor package.

### BACKGROUND

Semiconductor packages can be used in electronic devices, such as mobile phones and fitness trackers to track movements and health data. As the size of electronic devices decreases, there is a need to join multiple semiconductor packages in a limited space.

### BRIEF DESCRIPTION OF THE DRAWINGS

Aspects of the present disclosure are best understood from the following detailed description when read with the accompanying figures.

FIG. 1 illustrates a cross-sectional view of a semiconductor device with multiple semiconductor packages, in accordance with some embodiments.

FIG. 2 illustrates a cross-sectional view of another semiconductor device with multiple semiconductor packages, in accordance with some embodiments.

FIG. 3 illustrates a top view of a semiconductor device with multiple semiconductor packages, in accordance with some embodiments.

FIG. 4 is a flow diagram of a method for fabricating a semiconductor device with multiple semiconductor packages, in accordance with some embodiments.

FIGS. 5-15 illustrate cross-sectional views of a semiconductor device with multiple semiconductor packages at various stages of its fabrication process, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the embodiments and/or configurations discussed herein.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., 1%, +2%, +3%, ±4%, +5% of the value). These values are merely examples and are not intended to be limiting. The terms “about” and “substantially” can refer to a percentage of the values as interpreted by those skilled in relevant art(s) in light of the teachings herein.

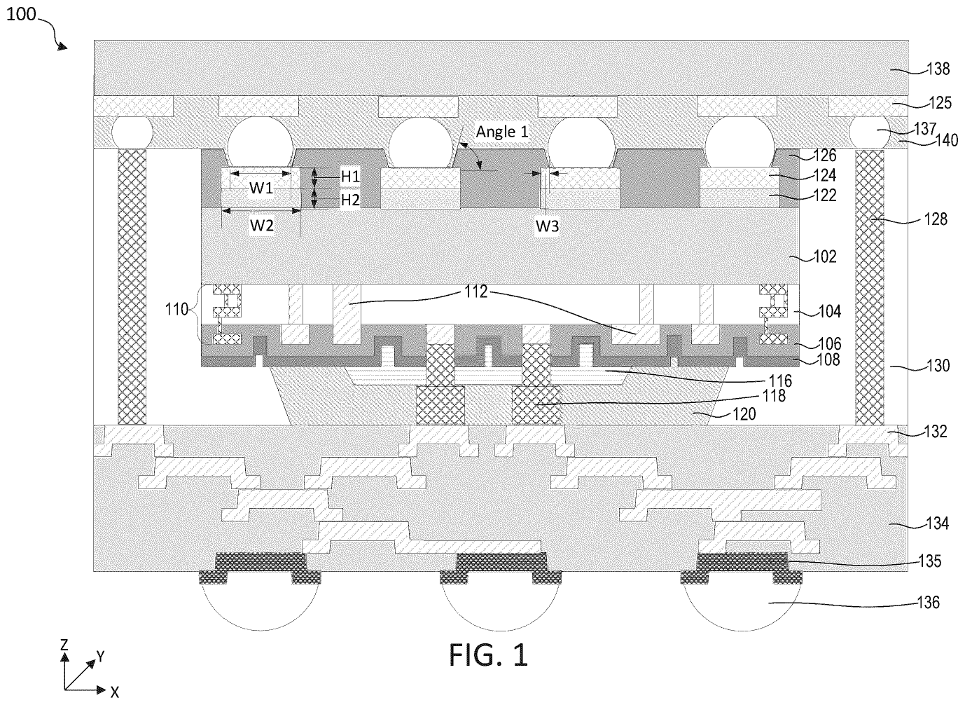

The discussion of elements in FIGS. 1-3 and 5-15 with the same annotations applies to each other, unless mentioned otherwise.

Semiconductor devices with multiple semiconductor packages can be used in electronics devices, such as mobile phones and fitness trackers to track movements and health data. A first semiconductor package can be a system-on-a-chip (SOC). The SOC can include an inertial sensor, a gyroscope sensor, a pulse sensor, other types of sensors, and combinations thereof. A second semiconductor package can be a storage device. The storage device can include a dynamic random-access memory (DRAM), a NAND flash memory, other types of memory devices, and combinations thereof. A third semiconductor package can be a power management device. Other types of electronic components can be included in the first, second, and third semiconductor packages. As the size of electronic devices (e.g., mobile phones and fitness trackers) decreases, the multiple semiconductor packages need to be joined in a limited space.

A die attach film (DAF) can be formed on the first semiconductor package. First joint pads, such as copper (Cu) pads, can be formed within the DAF. In some embodiments, bottom surfaces of the first joint pads can be buried in the DAF and not in direct contact with the first semiconductor package. Top surfaces of the first joint pads can be substantially coplanar with a top surface of the DAF. A ball grid array (BGA) can be soldered between the first joint pads and second joint pads of the second semiconductor package. The first and second semiconductor packages can be stacked vertically, such as in the z-direction, to save space. However, due to the different mechanical properties between the first joint pads and the DAF, cracks can occur at the interfaces between the first joint pads and the DAF. Furthermore, because the first joint pads are not in direct contact with the first semiconductor package and there are no portions of the DAF that are above the first joint pads, delamination of the first joint pads can occur. Cracks and delamination can reduce the reliability of the semiconductor devices with multiple semiconductor packages.

The present disclosure provides example semiconductor devices with multiple semiconductor packages with improved reliability and an example method for fabricating the same. Adhesion layers, such as titanium (Ti) and chromium (Cr) layers, can be formed in contact with a first semiconductor package. First joint pads can be formed in contact with the adhesion layers. A DAF can be formed on the first semiconductor package and the first joint pads. The DAF can have slanted sidewalls. The slanted sidewalls can cover end portions of the adhesion layers and the first joint pads. The slanted sidewalls can expose middle portions of the first joint pads. A BGA can be soldered between the exposed middle portions of the first joint pads and second joint pads of a second semiconductor package. Because of the similar mechanical properties between the first joint pads and the adhesion layers, cracks at the interfaces between the first joint pads and the adhesion layers can be reduced. The first joint pads and the adhesion layers are in direct contact with the first semiconductor package. The adhesion layers can increase the adhesion of the first joint pads to the first semiconductor package. The slanted sidewalls of the DAF covering the end portions of the first joint pads and the adhesion layers can also improve bonding robustness. Therefore, there can be reduced delamination of the first joint pads. A reduced number of cracks and reduced delamination can improve the reliability of the semiconductor devices with multiple semiconductor packages.

FIG. 1 illustrates a cross-sectional view of a semiconductor device 100 with a first semiconductor package 102 and a second semiconductor package 138, according to some embodiments. Semiconductor device 100 can further include an interlayer dielectric (ILD) layer 104, a first passivation layer 106, a second passivation layer 108, seal rings 110, a first redistribution layer (RDL) 112, a polyimide layer 116, input/output (I/O) connections 118, an I/O connection protective layer 120, adhesion layers 122, first joint pads 124, second joint pads 125, a DAF 126, through-interposer via (TIV) structures 128, a molding layer 130, second RDLs 132, an inter-metal dielectric (IMD) layer 134, under-bump metallization (UBM) layers 135, a first BGA 136, a second BGA 137, and a filling layer 140.

First semiconductor package 102 can be a SOC. First semiconductor package 102 can include an inertial sensor, a gyroscope sensor, a pulse sensor, other types of electronic sensors, and combinations thereof. First semiconductor package 102 can include transistors, resistors, capacitors, inductors, interconnect structures, other types of components and structures, and combinations thereof. Second semiconductor package 138 can be a storage device. Second semiconductor package 138 can include a DRAM, a NAND flash memory, other types of memory devices, and combinations thereof. Second semiconductor package 138 can include transistors, word lines, bit lines, resistors, capacitors, inductors, interconnect structures, other types of components and structures, and combinations thereof.

ILD layer 104 can be disposed below first semiconductor package 102. First passivation layer 106 can be disposed below ILD layer 104. Second passivation layer 108 can be disposed below first passivation layer 106. IMD layer 134 can be disposed below I/O connections 118 and I/O connection protective layer 120. ILD layer 104, first passivation layer 106, second passivation layer 108, and IMD layer 134 can include an insulating material, such as silicon oxide (SiOₓ), silicon nitride (SiN), silicon carbon nitride (SiCN), silicon oxycarbon nitride (SiOCN), germanium oxide (GeOₓ), silicon germanium oxide (SiGeOₓ), and combinations thereof.

Seal rings 110 can be disposed within ILD layer 104 and first passivation layer 106. Seal rings 110 can include multiple metal rings and metal support structures. Seal rings 110 can be disposed near edge portions of first semiconductor package 102. First semiconductor packages 102 can be formed in an array. After ILD layer 104, first passivation layer 106, second passivation layer 108, first RDLs 112, polyimide layers 116, I/O connections 118, I/O connection protective layers 120, adhesion layers 122, first joint pads 124, and DAF 126 are formed on first semiconductor packages 102, grooves can be formed on the array of first semiconductor packages 102 between adjacent first semiconductor packages 102 by a laser grooving process. A dicing saw can follow the grooves and dice the array of first semiconductor packages 102 into individual first semiconductor packages 102. During the laser grooving process and the mechanical dicing process, vibrations and static electrical charges can damage the electrical connections between first semiconductor packages 102 and first RDLs 112. Seal rings 110 can reduce the vibrations and release the static electrical charges, hence protecting the electrical connections between first semiconductor packages 102 and first RDLs 112.

First RDL 112 can be disposed within ILD layer 104 and first passivation layer 106. First RDL 112 can include multiple metal via structures and metal lines. I/O connections 118 can be disposed through first passivation layer 106 and second passivation layer 108. I/O connections 118 can be electrically coupled to first RDL 112. TIV structures 128 can be disposed adjacent to first semiconductor packages 102. TIV structures 128 can be electrically coupled to second RDLs 132 and second BGA 137. TIV structures 128 can electrically couple first semiconductor package 102 and second semiconductor package 138. Second RDLs 132 can be disposed within IMD layer 134. Second RDLs 132 can include multiple metal via structures and metal lines. In some embodiments, there can be one or more layers of second RDLs 132. UBM layers 135 can be disposed below IMD layer 134.

Seal rings 110, first RDL 112, I/O connections 118, TIV structures 128, second RDLs 132, and UBM layers 135 can include a suitable conductive material, such as tungsten (W), molybdenum (Mo), nickel (Ni), bismuth (Bi), scandium (Sc), Ti, Cu, cobalt (Co), silver (Ag), aluminum (Al), titanium aluminum nitride (TiAlN), tantalum carbide (TaC), tantalum carbonitride (TaCN), tantalum silicon nitride (TaSiN), manganese (Mn), zirconium (Zr), titanium nitride (TiN), tantalum nitride (TaN), ruthenium (Ru), tungsten nitride (WN), titanium carbide (TiC), titanium aluminum carbide (TiAlC), tantalum aluminum carbide (TaAlC), metal alloys, and combinations thereof.

In some embodiments, barrier layers (not shown in FIG. 1) can be disposed before seal rings 110, first RDL 112, I/O connections 118, TIV structures 128, second RDLs 132, and UBM layers 135 are formed. The barrier layers can include any suitable material, such as a metal oxide (MOₓ), a metal nitride (MNₓ), a metal carbide (MCₓ), a metalaluminate (MAlₓO_{y}), a combination of metal oxides (M1Oₓ/M2Oₓ), a metal-silicate (MSiOₓ), and combinations thereof. In some embodiments, the metal in the above-mentioned materials is a transition metal, such as hafnium (Hf), Zr, Ti, and Al, a rare earth metal, such as yttrium (Y), ytterbium (Yb), erbium (Er), and combinations thereof. In some embodiments, the barrier layers can include dielectric materials, such as SiN, SiOCN, SiCN, other suitable insulating materials, and combinations thereof.

Polyimide layer 116 can be disposed below second passivation layer 108. Polyimide layer 116 can provide mechanical support for I/O connections 118. Polyimide layer 116 can include polyimide and other suitable polymer materials.

I/O connection protective layer 120 can be disposed below second passivation layer 108 and polyimide layer 116. I/O connection protective layer 120 can encapsulate I/O connections 118. Molding layer 130 can be interposed between first semiconductor package 102 and TIV structures 128. Filling layer 140 can be disposed adjacent to second BGA 137 and interposed between DAF 126 and second semiconductor package 138. I/O connection protective layer 120, molding layer 130, and filling layer 140 can include an epoxy resin, a die encapsulant, and other suitable organic materials. The epoxy resin can be filled with fillers, such as silica (SiO₂). The epoxy resin can have various filler sizes, filler shapes, and filler contents. In some embodiments, filling layer 140 can include an epoxy resin with smaller-sized fillers than molding layer 130.

First BGA 136 can be disposed below UBM layers 135. Second BGA 137 can be interposed between first joint pads 124 and second joint pads 125. Second BGA 137 can be interposed between TIV structures 128 and second joint pads 125. First BGA 136 and second BGA 137 can include an array of solder balls. The solder balls can include a metal alloy, such as tin (Sn) and lead (Pb).

Adhesion layers 122 can be in contact with first semiconductor package 102. Adhesion layers 122 can include Ti, Cr, and other metals that can improve adhesion. Adhesion layers 122 can have a thickness H2 between about 100 nm and about 0.5 μm, between about 50 nm and about 0.8 μm, and between about 10 nm and about 1 μm. If thickness H2 is greater than about 1 μm, the fabrication time, manufacturing cost, and device size can be too great. If thickness H2 is less than about 10 nm, adhesion layers 122 cannot improve adhesion of first joint pads 124 to first semiconductor package 102.

First joint pads 124 can be in contact with adhesion layers 122. Second joint pads 125 can be disposed below second semiconductor package 138. First joint pads 124 and second joint pads 125 can include Cu and/or other suitable conductive materials. First joint pads 124 can have a thickness H1 between about 15 μm and about 200 μm, between about 5 μm and about 250 μm, and between about 0.5 μm and about 300 μm. If thickness H1 is greater than about 300 μm, the fabrication time, manufacturing cost, and device size can be too great. If thickness H1 is less than about 0.5 μm, the solderability of first joint pads 124 can be insufficient for second BGA 137 to attach to first joint pads 124. A ratio H1/H2 between thickness H1 and thickness H2 can be between about 50 and about 100, between about 30 and about 200, and between about 10 and about 300. If the ratio H1/H2 is greater than about 300, adhesion layers 122 cannot improve adhesion of first joint pads 124 to first semiconductor package 102. If the ratio H1/H2 is less than about 10, the solderability of first joint pads 124 can be insufficient for second BGA 137 to attach to first joint pads 124.

Adhesion layers 122 and first joint pads 124 can have a width W2 between about 100 μm and about 1000 μm, between about 50 μm and about 1500 μm, and between about 20 μm and about 2000 μm. Middle portions of first joint pads 124 exposed by the slanted sidewalls of DAF 126 can have a width W1 between about 80 μm and about 800 μm, between about 40 μm and about 1400 μm, and between about 15 μm and about 1800 μm. If width W1 is greater than about 1800 μm, or if width W2 is greater than about 2000 μm, the fabrication time, manufacturing cost, and device size can be too great and the number of solder balls per unit area of second BGA 137 can be too low. If width W1 is less than about 15 μm, or if width W2 is less than about 20 μm, the solderability of first joint pads 124 can be insufficient for second BGA 137 to attach to first joint pads 124. A ratio W2/W1 between width W2 and width W1 can be between about 2 and about 5, between about 1.5 and about 8, and between about 1.2 and about 10. If the ratio W2/W1 is less than about 1.2, the slanted sidewalls of DAF 126 can cover insufficient end portions of first joint pads 124 and leave large exposed areas of the middle portions of first joint pads 124. The solder balls can spread too easily in the middle portions of first joint pads 124 with large exposed areas and can be too flat. Flat solder balls cannot connect first joint pads 124 and second joint pads 125 effectively, which can reduce reliability. If the ratio W2/W1 is greater than about 10, the solderability of first joint pads 124 can be insufficient for second BGA 137 to attach to first joint pads 124. First joint pads 124 and adhesion layers 122 are in direct contact with first semiconductor package 102. Adhesion layers 122 can increase the adhesion of first joint pads 124 to first semiconductor package 102. Furthermore, because of the similar mechanical properties between first joint pads 124 and adhesion layers 122, cracks at the interfaces between first joint pads 124 and adhesion layers 122 can be reduced. A reduced number of cracks and improved adhesion can improve the reliability of the joint between first semiconductor package 102 and second semiconductor package 138.

DAF 126 can be disposed on first semiconductor package 102 and first joint pads 124. DAF 126 can include a polymer and other suitable organic materials. DAF 126 can include slanted sidewalls. An angle 1 between the slanted sidewalls and a horizontal direction, such as the x-direction, can be between about 50° and about 60°, between about 40° and about 70°, and between about 30° and about 80°. If angle 1 is less than about 30°, the slanted sidewalls of DAF 126 can cover insufficient end portions of first joint pads 124 and leave large exposed areas of the middle portions of first joint pads 124. The solder balls can spread too easily in the middle portions of first joint pads 124 with large exposed areas and can be too flat. Flat solder balls cannot connect first joint pads 124 and second joint pads 125 effectively, which can reduce reliability. If angle 1 is greater than about 80°, the solderability of first joint pads 124 can be insufficient for second BGA 137 to attach to first joint pads 124. If angle 1 is greater than about 80°, there can also be increased delamination of first joint pads 124.

The slanted sidewalls of DAF 126 can cover end portions of first joint pads 124 and adhesion layers 122. The covered end portions of first joint pads 124 and adhesion layers 122 can have a width W3 between about 50 μm and about 500 μm, between about 25 μm and about 750 μm, and between about 10 μm and about 1000 μm. If width W3 is less than about 10 μm, first joint pads 124 can delaminate too easily. If width W3 is greater than about 1000 μm, the solderability of first joint pads 124 can be insufficient for second BGA 137 to attach to first joint pads 124. A ratio W3/W2 between width W3 and width W2 can be between about 0.1 and about 0.3, between about 0.05 and about 0.4, and between about 0.01 and about 0.45. If the ratio W3/W2 is less than about 0.01, first joint pads 124 can delaminate too easily. If the ratio W3/W2 is greater than about 0.45, the solderability of first joint pads 124 can be insufficient for second BGA 137 to attach to first joint pads 124. The slanted sidewalls of DAF 126 covering the end portions of first joint pads 124 and adhesion layers 122 can improve first joint pads 124 bonding robustness, reduce delamination of first joint pads 124, and improve the reliability of the joint between first semiconductor package 102 and second semiconductor package 138.

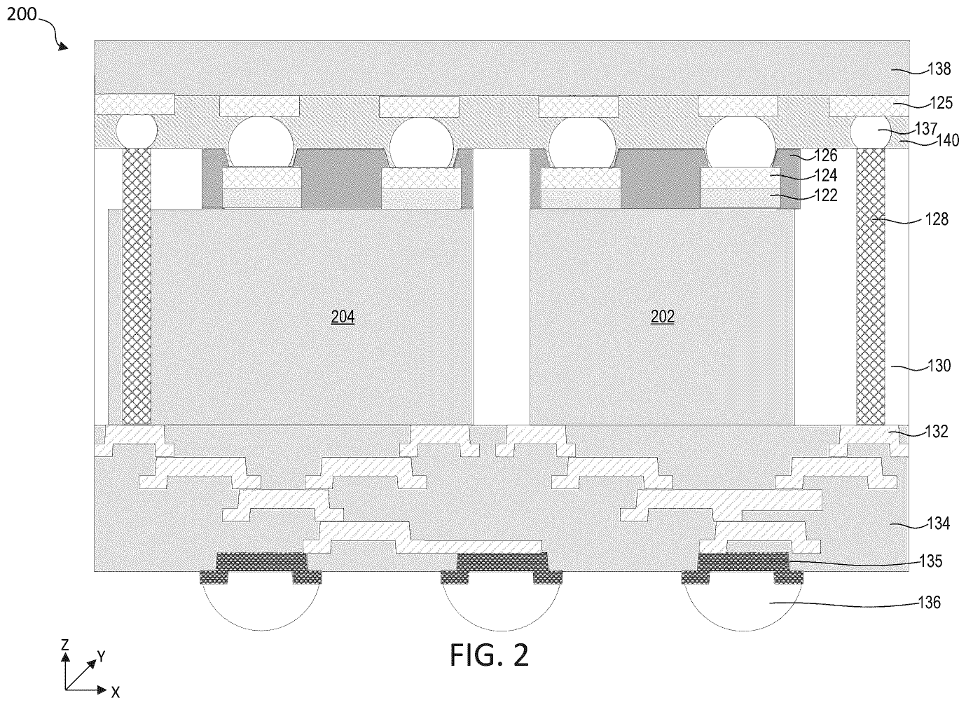

FIG. 2 illustrates a cross-sectional view of a semiconductor device 200 with a first semiconductor package 202, second semiconductor package 138, and a third semiconductor package 204, according to some embodiments. First semiconductor package 202 can include a SOC that can include an inertial sensor, a gyroscope sensor, a pulse sensor, other types of electronic sensors, and combinations thereof. First semiconductor package 202 can further include an ILD layer, a RDL, passivation layers, a polyimide layer, I/O connections, and an I/O connection protective layer. Second semiconductor package 138 can include a DRAM, a NAND flash memory, other types of memory devices, and combinations thereof. Third semiconductor package 204 can be disposed adjacent to first semiconductor package 202. Third semiconductor package 204 can include a power management device. Third semiconductor package 204 can be electrically coupled to first semiconductor package 202 and second semiconductor package 138. In some embodiments, semiconductor device 200 can be a self-sufficient device without having to interact with other devices, such as a motherboard of a mobile phone. Both first semiconductor package 202 and third semiconductor package 204 can be joined to second semiconductor package 138 by adhesion layers 122, first joint pads 124, DAF 126, second BGA 137, and second joint pads 125.

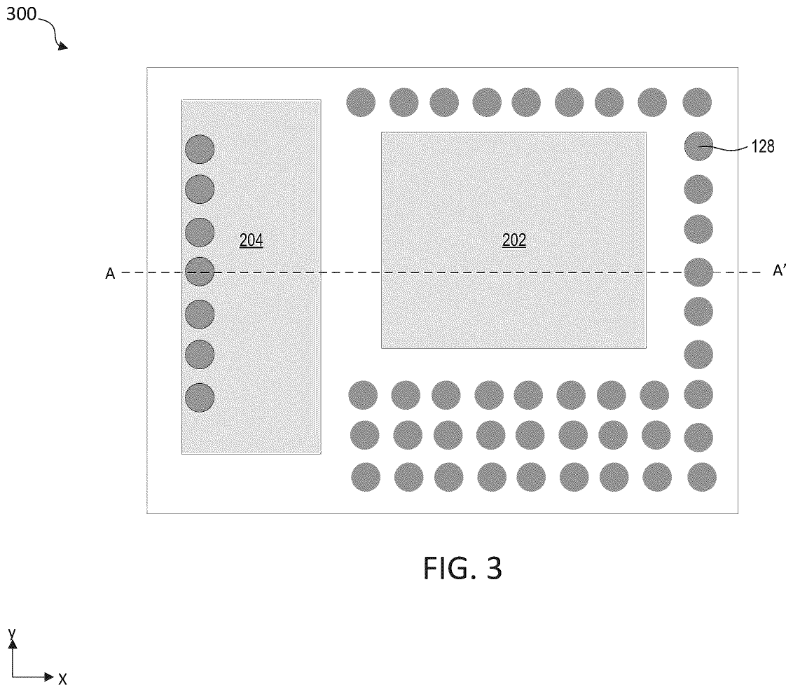

FIG. 3 illustrates a top view of a semiconductor device 300 with first semiconductor package 202 and third semiconductor package 204, according to some embodiments. In some embodiments, FIG. 3 can be a top view of semiconductor device 200 as shown in FIG. 2. In some embodiments, FIG. 2 can be a cross-sectional view of semiconductor device 300 as shown in FIG. 3 along line A-A′. Semiconductor device 300 can include TIV structures 128 at various locations. Adhesion layers 122, first joint pads 124, and DAF 126 with slanted sidewalls can provide strong and reliable joints between first semiconductor package 202 and second semiconductor package 138, and between third semiconductor package 204 and second semiconductor package 138. Therefore, there can be no need for TIV structures 128 to provide additional mechanical support. Consequently, the quantities and the locations of TIV structures 128 can be more flexible. For example, as shown in FIG. 3, there can be no TIV structures 128 on the left side of third semiconductor package 204. This can save chip space and reduce the size of semiconductor device 300.

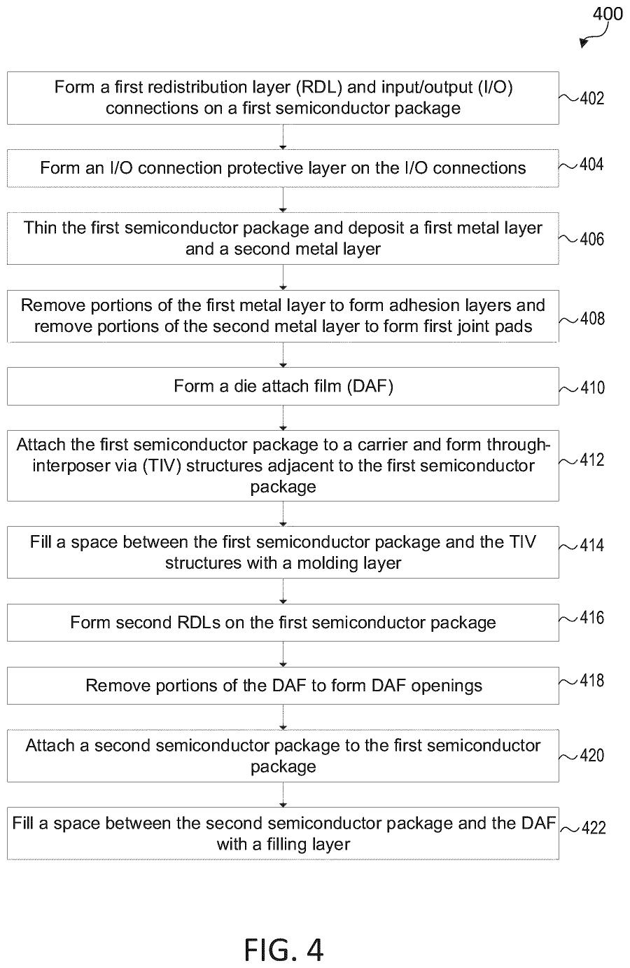

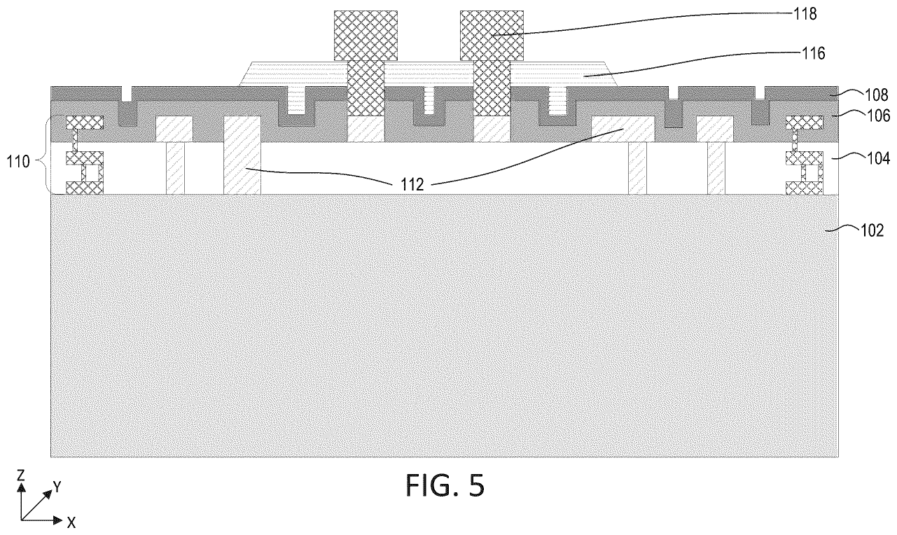

FIG. 4 is a flow diagram of a method 400 for fabricating semiconductor device 100 with first semiconductor package 102 and second semiconductor package 138 as shown in FIG. 1, according to some embodiments. For illustrative purposes, the operations illustrated in FIG. 4 will be described with reference to the example fabrication process for fabricating semiconductor device 100 as illustrated in FIGS. 5-15. FIGS. 5-15 are cross-sectional views of semiconductor device 100 at various stages of fabrication, according to some embodiments. Additional fabrication operations can be performed between the various operations of method 400 and are omitted for simplicity. These additional fabrication operations are within the spirit and the scope of this disclosure. Moreover, not all operations may be required to perform the disclosure provided herein. Additionally, some of the operations can be performed simultaneously or in a different order than the ones shown in FIG. 4. Elements in FIGS. 5-15 with the same annotations as the elements in FIG. 1 are described above. It should be noted that method 400 may not produce a complete semiconductor device 100. Accordingly, it is understood that additional processes can be provided before, during, and after method 400, and that some other processes may only be briefly described herein.

Referring to FIG. 4, in operation 402, a first RDL and I/O connections are formed on a first semiconductor package. For example, as shown in FIG. 5, first RDL 112 and I/O connections 118 can be formed on first semiconductor package 102. ILD layer 104, first passivation layer 106, and second passivation layer 108 can be deposited on first semiconductor package 102 by a chemical vapor deposition (CVD) process or a physical vapor deposition (PVD) process. Portions of ILD layer 104 and first passivation layer 106 can be removed by a dry etch process or a wet etch process to form metal line openings, metal via openings, and seal ring openings. The metal line openings, the metal via openings, and the seal ring openings can be filled with a metal by a CVD process, a PVD process, an atomic layer deposition (ALD) process, a metal organic chemical vapor deposition (MOCVD) process, or a plasma-enhanced chemical vapor deposition (PECVD) process to form first RDL 112 and seal rings 110. Polyimide layer 116 with I/O connection openings can be formed by a photolithography process. The I/O connection openings can be filled with a metal by a CVD process, a PVD process, a MOCVD process, a PECVD process, a sputtering process, or an electroplating process to form I/O connections 118.

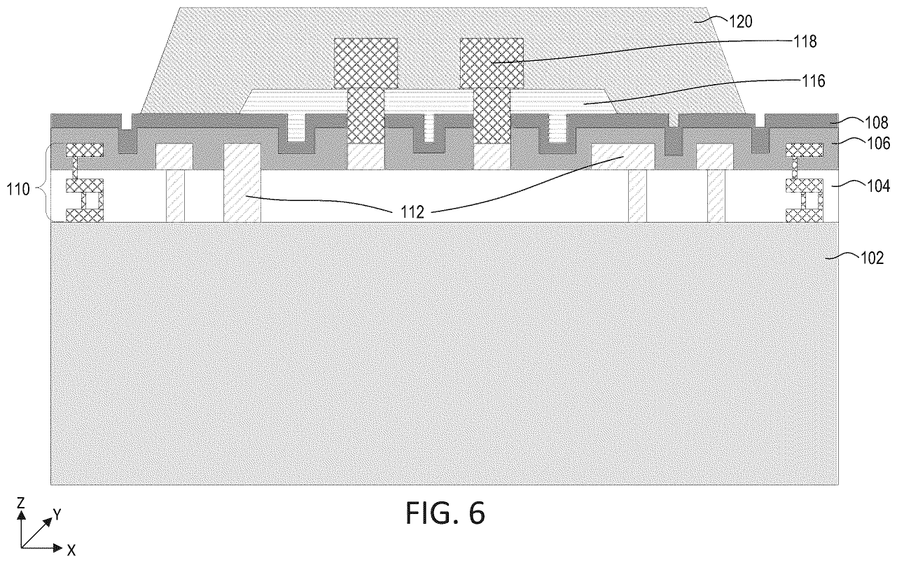

Referring to FIG. 4, in operation 404, an I/O connection protective layer is formed on the I/O connections. For example, as shown in FIG. 6, I/O connection protective layer 120 can be formed on I/O connections 118. I/O connection protective layer 120 can be formed by spin coating a polymer layer on I/O connections 118 and removing portions of the polymer layer by a dry etch process. In some embodiments, I/O connection protective layer 120 can be formed by a molding process. An epoxy resin can be poured into a mold around I/O connections 118 and cured to form I/O connection protective layer 120.

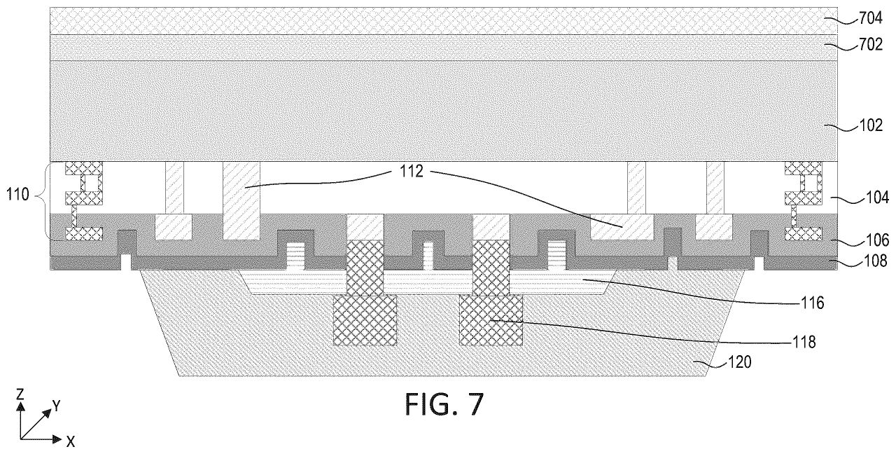

Referring to FIG. 4, in operation 406, the first semiconductor package is thinned and a first metal layer and a second metal layer are deposited on the thinned first semiconductor package. For example, as shown in FIG. 7, first semiconductor package 102 can be flipped and thinned and a first metal layer 702 and a second metal layer 704 can be deposited on the thinned first semiconductor package 102. First metal layer 702 can be deposited on first semiconductor package 102 by a CVD process, a PVD process, a MOCVD process, a PECVD process, or a sputtering process. Second metal layer 704 can be deposited on first metal layer 702 by a CVD process, a PVD process, a MOCVD process, a PECVD process, a sputtering process, or an electroplating process.

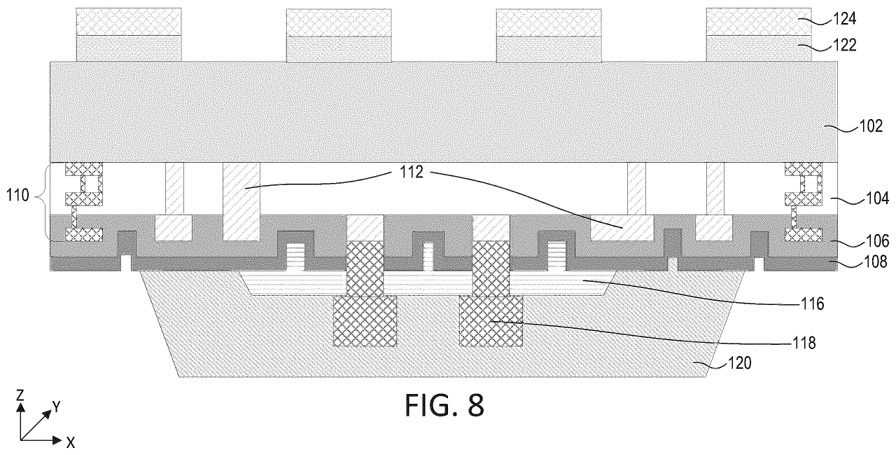

Referring to FIG. 4, in operation 408, portions of the first metal layer are removed to form adhesion layers and portions of the second metal layer are removed to form first joint pads. For example, as shown in FIG. 8, portions of first metal layer 702 can be removed to form adhesion layers 122 and portions of second metal layer 704 can be removed to form first joint pads 124. Portions of first metal layer 702 and second metal layer 704 can be removed by a dry etch process or a wet etch process. In some embodiments, the dry etch process can include etchants with an (i) oxygen-containing gas; (ii) methane (CH₄); (iii) a fluorine-containing gas (e.g., carbon tetrafluoride (CF₄), sulfur hexafluoride (SF₆), difluoromethane (CH₂F₂), trifluoromethane (CHF₃), and/or hexafluoroethane (C₂F₆)); (iv) a chlorine-containing gas (e.g., chlorine (Cl₂), chloroform (CHCl₃), carbon tetrachloride (CCl₄), and/or boron trichloride (BCl₃)); (v) a bromine-containing gas (e.g., hydrogen bromide (HBr) and/or bromoform (CHBr₃)); (vi) an iodine-containing gas; (vii) other suitable etching gases and/or plasmas; or (viii) combinations thereof. In some embodiments, the wet etch process can include etching in diluted hydrofluoric acid (DHF), potassium hydroxide (KOH) solution, hydrogen peroxide (H₂O₂), ammonia (NH₃), a solution containing hydrofluoric acid (HF), nitric acid (HNO₃), acetic acid (CH₃COOH), or combinations thereof. The etch process to form adhesion layers 122 and first joint pads 124 can be a timed etch. The areas to form adhesion layers 122 and first joint pads 124 can be defined by a photoresist layer (not shown in FIG. 8). In some embodiments, first semiconductor package 102 can function as an etch stop layer for the etch process. Adhesion layers 122 can increase the adhesion of first joint pads 124 to first semiconductor package 102. Furthermore, because of the similar mechanical properties between first joint pads 124 and adhesion layers 122, cracks at the interfaces between first joint pads 124 and adhesion layers 122 can be reduced. A reduced number of cracks and improved adhesion can improve the reliability of the joint between first semiconductor package 102 and second semiconductor package 138.

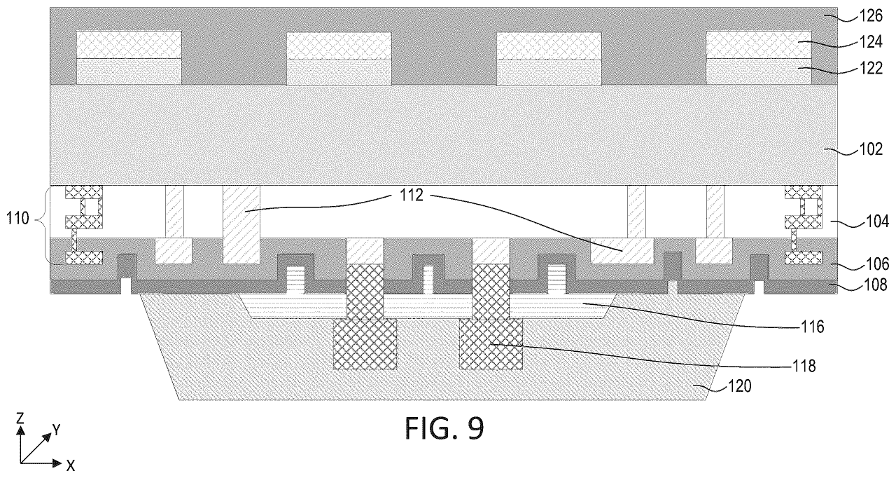

Referring to FIG. 4, in operation 410, a DAF is formed. For example, as shown in FIG. 9, DAF 126 can be formed. DAF 126 can be spin coated on first semiconductor package 102, adhesion layers 122, and first joint pads 124. The thickness of DAF 126 can be controlled by the spin coating speed. A higher spin coating speed can result in a thinner DAF 126. A lower spin coating speed can result in a thicker DAF 126. Up to operation 410, first semiconductor packages 102 can be in an array. After ILD layer 104, first passivation layer 106, second passivation layer 108, first RDLs 112, polyimide layers 116, I/O connections 118, I/O connection protective layers 120, adhesion layers 122, first joint pads 124, and DAF 126 are formed on first semiconductor packages 102, grooves can be formed on the array of first semiconductor packages 102 between adjacent first semiconductor packages 102 by a laser grooving process. A dicing saw can follow the grooves and dice the array of first semiconductor packages 102 into individual first semiconductor packages 102. During the laser grooving process and the mechanical dicing process, vibrations and static electrical charges can damage the electrical connections between first semiconductor packages 102 and first RDLs 112. Seal rings 110 can reduce the vibrations and release the static electrical charges, hence protecting the electrical connections between first semiconductor packages 102 and first RDLs 112. After operation 410, the array of first semiconductor packages 102 are diced into individual first semiconductor packages 102. Subsequent operations are performed on individual first semiconductor packages 102.

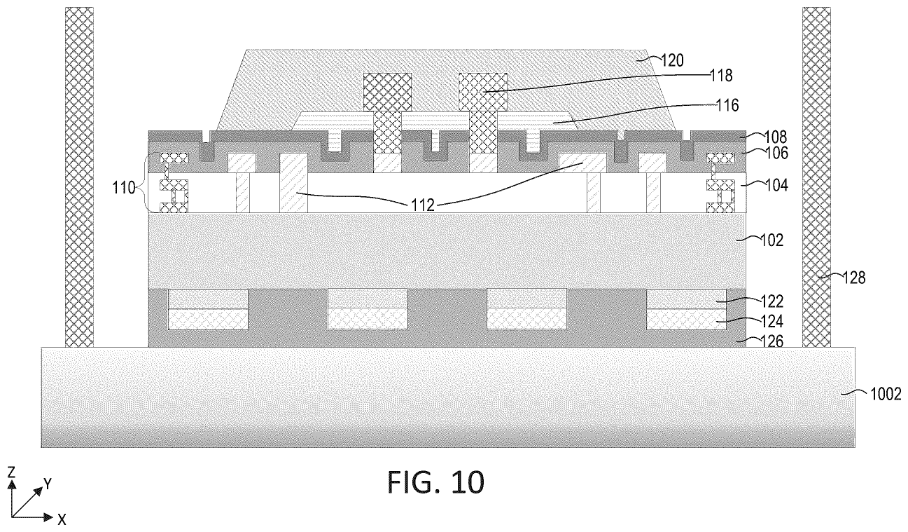

Referring to FIG. 4, in operation 412, the first semiconductor package is attached to a carrier and TIV structures are formed adjacent to the first semiconductor package. For example, as shown in FIG. 10, first semiconductor package 102 can be flipped and attached to a carrier 1002 and TIV structures 128 can be formed adjacent to first semiconductor package 102. Carrier 1002 can be a glass carrier or a Si carrier. DAF 126 can function as an adhesive to attach first semiconductor package 102 to carrier 1002. A photoresist layer (not shown in FIG. 10) can be spin coated on carrier 1002. TIV structure openings can be formed in the photoresist layer by a photolithography process. TIV structure openings can be filled with a metal by a CVD process, a PVD process, a MOCVD process, a PECVD process, a sputtering process, or an electroplating process to form TIV structures 128. The photoresist layer can be removed by a liftoff process or a wet etch process.

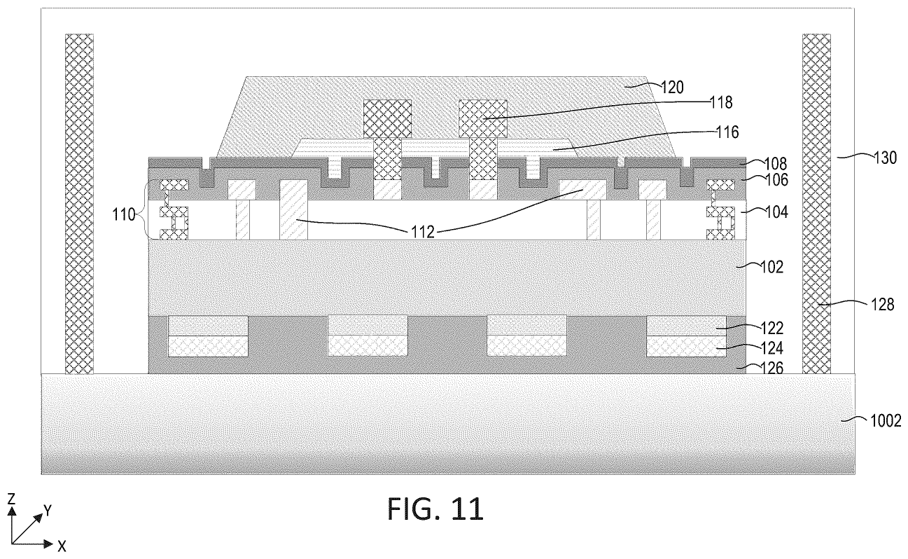

Referring to FIG. 4, in operation 414, a space between the first semiconductor package and the TIV structures is filled with a molding layer. For example, as shown in FIG. 11, a space between first semiconductor package 102 and TIV structures 128 can be filled with molding layer 130. Molding layer 130 can be formed by spin coating a polymer layer on carrier 1002. In some embodiments, molding layer 130 can be formed by a molding process. An epoxy resin can be poured into a mold around TIV structures 128 and cured to form molding layer 130. In some embodiments, a chemical mechanical planarization (CMP) process can be performed to planarize top surfaces of TIV structures 128 and molding layer 130.

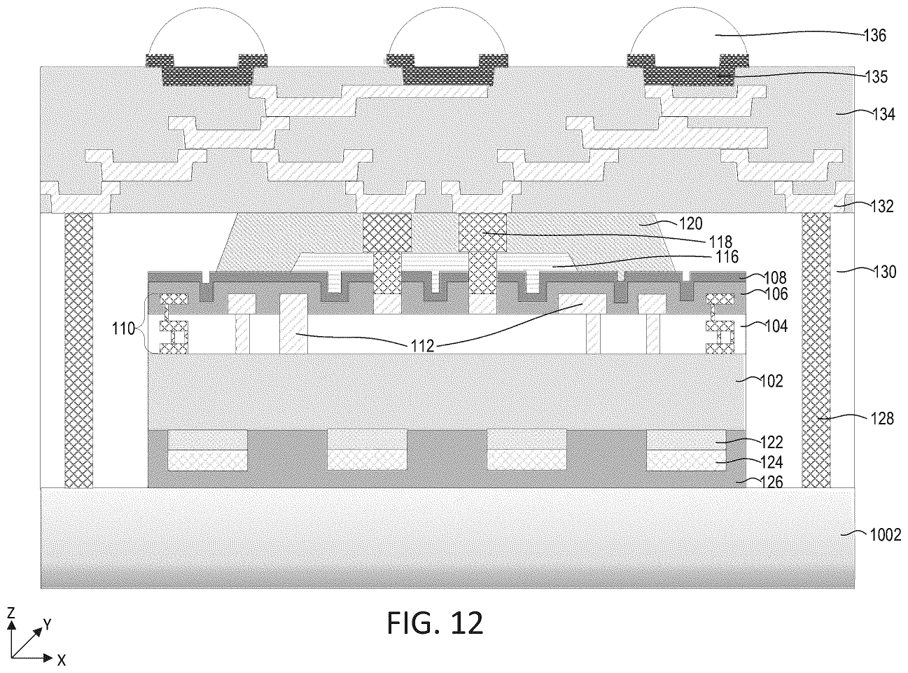

Referring to FIG. 4, in operation 416, second RDLs are formed on the first semiconductor package. For example, as shown in FIG. 12, second RDLs 132 can be formed on first semiconductor package 102. IMD layer 134 can be deposited on molding layer 130, I/O connection protective layer 120, and TIV structures 128 by a CVD process or a PVD process. Portions of IMD layer 134 can be removed by a dry etch process or a wet etch process to form metal line openings and metal via openings. The metal line openings and the metal via openings can be filled with a metal by a CVD process, a PVD process, an ALD process, a MOCVD process, or a PECVD process to form second RDLs 132. UBM openings can be formed in IMD layer 134 by a dry etch process or a wet etch process. The UBM openings can be filled with a metal by a CVD process, a PVD process, a MOCVD process, a PECVD process, a sputtering process, or an electroplating process to form UBM layers 135. First BGA 136 can be soldered on UBM layers 135.

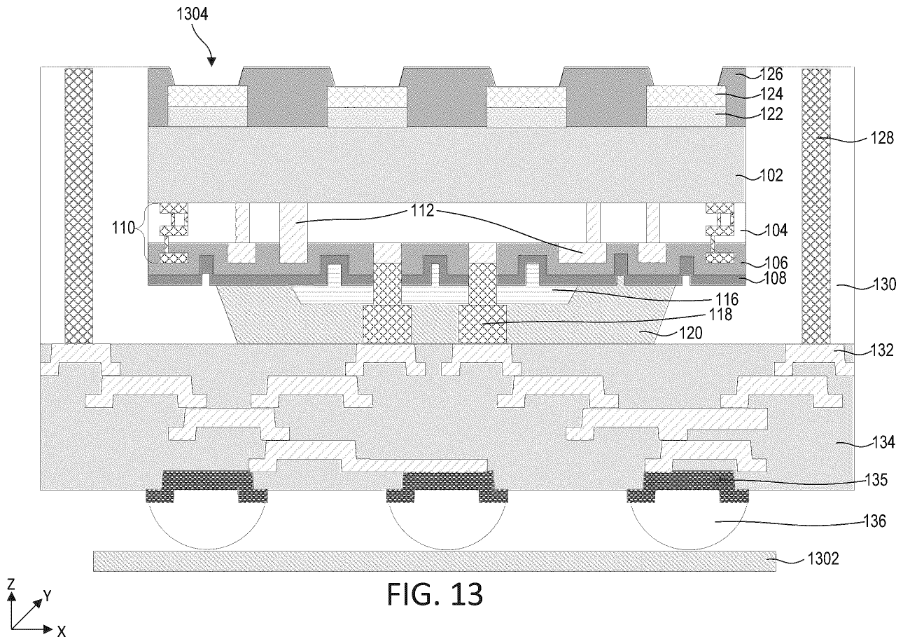

Referring to FIG. 4, in operation 418, portions of the DAF are removed to form DAF openings. For example, as shown in FIG. 13, portions of DAF 126 can be removed to form DAF openings 1304. First semiconductor package 102 can be flipped and a protective thin film 1302 can be attached to first BGA 136 to protect first BGA 136. Protective thin film 1302 can be a polymer or other suitable organic materials. Carrier 1002 can be removed. In some embodiments, carrier 1002 can be released by heating DAF 126. In some embodiments, portions of DAF 126 can be removed by a dry etch process or a wet etch process. The areas of DAF 126 to be removed can be defined by a photolithographic pattern. In some embodiments, portions of DAF 126 can be removed by a laser milling process. The laser used can be an excimer laser, a neodymium-doped yttrium aluminum garnet (Nd:YAG) laser, or a carbon dioxide (CO₂) laser having a wavelength ranging from about 200 nm to about 11 μm. The laser milling process can be a single-pulse milling process, a percussion milling process, a trepanning milling process, or a helical milling process. The total laser power can range from about 10 mJ to about 50 J, from about 1 mJ to about 80 J, and from about 0.1 mJ to about 100 J. If the total laser energy is greater than about 100 J, the middle portions of first joint pads 124 exposed by DAF openings 1304 can be too great. The solder balls can spread too easily in the middle portions of first joint pads 124 with large exposed areas and can be too flat. Flat solder balls cannot connect first joint pads 124 and second joint pads 125 effectively, which can reduce reliability. If the total laser power is less than about 0.1 mJ, the middle portions of first joint pads 124 exposed by DAF openings 1304 can be too small. The solderability of first joint pads 124 can be insufficient for second BGA 137 to attach to first joint pads 124. The total laser power can depend on the frequency of the laser shots and the duration of each laser shot. DAF openings 1304 can have slanted sidewalls covering first joint pads 124. The slanted sidewalls of DAF openings 1304 covering the end portions of first joint pads 124 and adhesion layers 122 can improve first joint pads 124 bonding robustness, reduce delamination of first joint pads 124, and improve the reliability of the joint between first semiconductor package 102 and second semiconductor package 138.

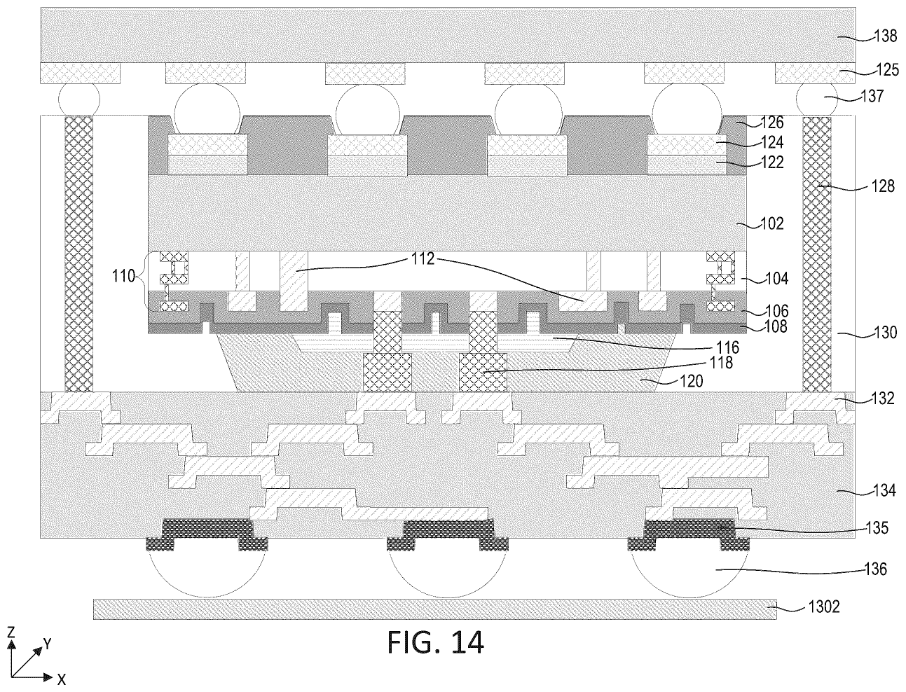

Referring to FIG. 4, in operation 420, a second semiconductor package is attached to the first semiconductor package. For example, as shown in FIG. 14, second semiconductor package 138 can be attached to first semiconductor package 102. Second joint pads 125 can be formed on second semiconductor package 138 by (i) depositing a metal layer by a CVD process, a PVD process, a MOCVD process, a PECVD process, a sputtering process, or an electroplating process; and (ii) removing portions of the metal layer by a dry etch process or a wet etch process. Second BGA 137 can be soldered between first joint pads 124 and second joint pads 125.

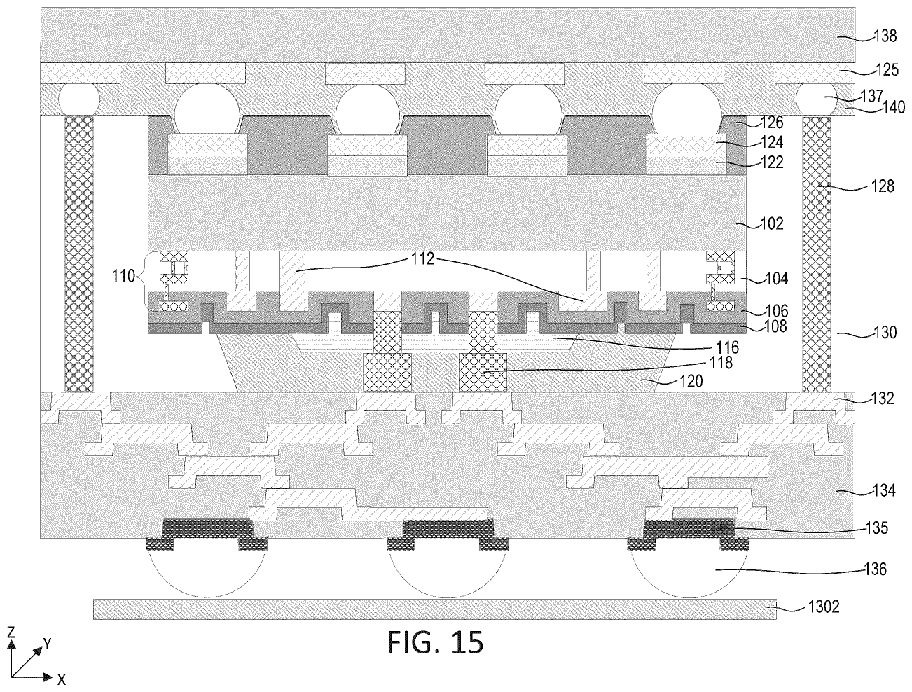

Referring to FIG. 4, in operation 422, a space between the second semiconductor package and the DAF is filled with a filling layer. For example, as shown in FIG. 15, a space between second semiconductor package 138 and DAF 126 can be filled with filling layer 140. Filling layer 140 can be formed by a molding process. In some embodiments, filling layer 140 can be formed by an injection molding process. An epoxy resin can be injected into the space around second BGA 137 and between second semiconductor package 138 and DAF 126. The epoxy resin can be cured to form filling layer 140. After filling layer 140 is formed and protective thin film 1302 is removed, semiconductor device 100 as shown in FIG. 1 can be formed.

The present disclosure provides example semiconductor devices (e.g., semiconductor devices 100, 200, and 300) with multiple semiconductor packages (e.g., first semiconductor packages 102 and 202, second semiconductor package 138, and third semiconductor package 204) with improved reliability and an example method (e.g., method 400) for fabricating the same. Adhesion layers (e.g., adhesion layers 122), such as titanium (Ti) and chromium (Cr) layers, can be formed in contact with a first semiconductor package (e.g., first semiconductor package 102). First joint pads (e.g., first joint pads 124) can be formed in contact with the adhesion layers. A DAF (e.g., DAF 126) can be formed on the first semiconductor package and the first joint pads. The DAF can have slanted sidewalls. The slanted sidewalls can cover end portions of the adhesion layers and the first joint pads. The slanted sidewalls can expose middle portions of the first joint pads. A BGA (e.g., second BGA 137) can be soldered between the exposed middle portions of the first joint pads and second joint pads (e.g., second joint pads 125) of a second semiconductor package (e.g., second semiconductor package 138). Because of the similar mechanical properties between the first joint pads and the adhesion layers, cracks at the interfaces between the first joint pads and the adhesion layers can be reduced. The first joint pads and the adhesion layers are in direct contact with the first semiconductor package. The adhesion layers can increase the adhesion of the first joint pads to the first semiconductor package. The slanted sidewalls of the DAF covering the end portions of the first joint pads and the adhesion layers can also improve bonding robustness. Therefore, there can be reduced delamination of the first joint pads. A reduced number of cracks and reduced delamination can improve the reliability of the semiconductor devices with multiple semiconductor packages.

In some embodiments, a structure includes an adhesion layer in contact with a first semiconductor package and a first joint pad in contact with the adhesion layer. The structure further includes a film layer disposed on the first semiconductor package and the first joint pad, where the film layer includes a slanted sidewall, the slanted sidewall covers an end portion of the adhesion layer and a first portion of the first joint pad, and the slanted sidewall exposes a second portion of the first joint pad. The structure further includes a solder ball attached to the second portion of the first joint pad and a second joint pad of a second semiconductor package.

In some embodiments, a structure includes a substrate including a first redistribution layer (RDL) and a first ball grid array (BGA) and an input/output (I/O) connection disposed on and electrically coupled to the first RDL. The structure further includes a second RDL disposed on and electrically coupled to the I/O connection and a system-on-a-chip (SOC) disposed on and electrically coupled to the second RDL. The structure further includes a joint section including an adhesion layer in contact with the SOC, a first joint pad in contact with the adhesion layer, and a die attach film (DAF) disposed on the SOC and covering end portions of the adhesion layer and the first joint pad. The structure further includes a second BGA attached to the first joint pad and a second joint pad of a semiconductor package.

In some embodiments, a method includes forming an adhesion layer in contact with a first semiconductor package and forming a first joint pad in contact with the adhesion layer. The method further includes forming a film layer on the first semiconductor package and the first joint pad, including forming a slanted sidewall of the film layer, covering an end portion of the adhesion layer and a first portion of the first joint pad, and exposing a second portion of the first joint pad. The method further includes forming a ball grid array (BGA) between the second portion of the first joint pad and a second joint pad of a second semiconductor package.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
an adhesion layer in contact with a first semiconductor package;
a first joint pad in contact with the adhesion layer;
a film layer disposed on the first semiconductor package and the first joint pad, wherein:
the film layer comprises a slanted sidewall;
the slanted sidewall covers an end portion of the adhesion layer and a first portion of the first joint pad; and
the slanted sidewall exposes a second portion of the first joint pad; and
a solder ball attached to the second portion of the first joint pad and a second joint pad of a second semiconductor package.

2. The structure of claim 1, wherein a thickness of the adhesion layer is between about 10 nm and about 1000 nm.

3. The structure of claim 1, wherein a thickness of the first joint pad is between about 0.5 μm and about 300 μm.

4. The structure of claim 1, wherein a ratio between a thickness of the first joint pad and a thickness of the adhesion layer is between about 10 and about 300.

5. The structure of claim 1, wherein a ratio between a width of the adhesion layer and a width of the second portion of the first joint pad is between about 1.2 and about 10.

6. The structure of claim 1, wherein an angle between the slanted sidewall and a horizontal direction is between about 30° and about 80°.

7. The structure of claim 1, further comprising:
a through-interposer via (TIV) structure disposed adjacent to the first semiconductor package and electrically coupling the first and second semiconductor packages;
a molding layer between the first semiconductor package and the TIV structure; and
a filling layer adjacent to the solder ball and between the film layer and the second semiconductor package.

8. The structure of claim 1, further comprising a first redistribution layer (RDL) and an input/output (I/O) connection disposed below the first semiconductor package, wherein the I/O connection is electrically coupled to one or more second RDLs disposed below the I/O connection.

9. The structure of claim 1, wherein the first semiconductor package comprises a system-on-a-chip (SOC) comprising one or more sensors, and wherein the second semiconductor package comprises one or more memory devices.

10. The structure of claim 1, further comprising a third semiconductor package disposed adjacent to the first semiconductor package and electrically coupled to the first and second semiconductor packages, wherein the third semiconductor package comprises a power management device.

11. A structure, comprising:
a substrate comprising a first redistribution layer (RDL) and a first ball grid array (BGA);
an input/output (I/O) connection disposed on and electrically coupled to the first RDL;
a second RDL disposed on and electrically coupled to the I/O connection;
a system-on-a-chip (SOC) disposed on and electrically coupled to the second RDL;
a joint section comprising:
an adhesion layer in contact with the SOC;
a first joint pad in contact with the adhesion layer; and
a die attach film (DAF) disposed on the SOC and covering end portions of the adhesion layer and the first joint pad; and
a second BGA attached to the first joint pad and a second joint pad of a semiconductor package.

12. The structure of claim 11, wherein a ratio between a thickness of the first joint pad and a thickness of the adhesion layer is between about 10 and about 300.

13. The structure of claim 11, wherein the DAF exposes a middle portion of the first joint pad, and wherein a ratio between a width of the adhesion layer and a width of the middle portion of the first joint pad is between about 1.2 and about 10.

14. The structure of claim 11, wherein the DAF comprises a slanted sidewall, and wherein an angle between the slanted sidewall and a horizontal direction is between about 30° and about 80°.

15. The structure of claim 11, wherein the joint section further comprises a filling layer adjacent to the second BGA and between the DAF and the semiconductor package.

16. The structure of claim 11, further comprising an other semiconductor package disposed adjacent to the SOC and electrically coupled to the SOC and the semiconductor package.

17. A method, comprising:
forming an adhesion layer in contact with a first semiconductor package;
forming a first joint pad in contact with the adhesion layer;
forming a film layer on the first semiconductor package and the first joint pad, comprising:
forming a slanted sidewall of the film layer;
covering an end portion of the adhesion layer and a first portion of the first joint pad; and
exposing a second portion of the first joint pad; and
forming a ball grid array (BGA) between the second portion of the first joint pad and a second joint pad of a second semiconductor package.

18. The method of claim 17, further comprising:
forming a through-interposer via (TIV) structure adjacent to the first semiconductor package;
forming a first redistribution layer (RDL) and an input/output (I/O) connection below the first semiconductor package; and
forming a second RDL below the I/O connection to electrically couple to the I/O connection and the TIV structure.

19. The method of claim 18, further comprising:
filling a space between the TIV structure and the first semiconductor package with a molding layer; and
filling a space adjacent to the BGA and between the film layer and the second semiconductor package with a filling layer.

20. The method of claim 17, wherein exposing the second portion of the first joint pad comprises removing a portion of the film layer by a laser milling process, a dry etch process, or a wet etch process.
